(19) United States
(12) Patent Application Publication
(10) Pub. No.: US 2025/0331256 A1
(43) Pub. Date: Oct. 23, 2025

(54) SEMICONDUCTOR STRUCTURE AND PREPARATION METHOD THEREFOR

(71) Applicant: Fujian Jinhua Integrated Circuit Co., Ltd., Fujian (CN)

(72) Inventors: Ding ZHANG, Fujian (CN); Yanduan LU, Fujian (CN); Jingjing YOU, Fujian (CN); Weiting LIU, Fujian (CN)

(73) Assignee: Fujian Jinhua Integrated Circuit Co., Ltd., Fujian (CN)

(21) Appl. No.: 18/830,594

(22) Filed: Sep. 11, 2024

(30) Foreign Application Priority Data
Apr. 23, 2024 (CN) 202410493939.X

(51) Int. Cl. H01L 29/08; H01L 29/423; H01L 29/51

(52) U.S. Cl. CPC H10D 62/151; H10D 64/514; H10D 64/683

(57) ABSTRACT

A semiconductor structure and a preparation method therefor, which relate to the field of semiconductor technology. The semiconductor structure includes a substrate, a source layer, a drain layer, a channel layer, a gate structure, a gate dielectric layer, and a dielectric layer. The source layer and the drain layer are stacked disposed on the substrate. The channel layer is located between the source layer and the drain layer. The gate structure is located on a side wall of the channel layer. The gate dielectric layer is located between the gate structure and the channel layer. A portion of the dielectric layer is arranged between the source layer and the gate structure. The source layer has a plurality of depressions extending towards the substrate, and the channel layer is partially filled into the depressions and electrically connected to the source layer.

### CROSS-REFERENCE TO RELATED APPLICATION

This application claims the priority benefit of China application serial no. 202410493939.X, filed on Apr. 23, 2024. The entirety of the above-mentioned patent application is hereby incorporated by reference herein and made a part of this specification.

### BACKGROUND

### Technical Field

The present application relates to the field of semiconductor technology, and in particular, to a semiconductor structure and a preparation method therefor.

### Description of Related Art

With the development of semiconductor technologies, semiconductor integrated circuits are more inclined towards small-sized design and high-density layout. It is increasingly difficult to further reduce size and ensure the performance of the semiconductor structures.

Due to the difficulty in sustained miniaturization of the manufacturing process of traditional planar metal-oxide-semiconductor (MOS) transistors, how to improve the traditional planar MOS transistors so as to reduce the geometric size of MOS transistors and/or improve the performance of transistor components has become an urgent technical problem to be solved at present.

### SUMMARY

In view of the above problems, the embodiments of the present application provide a semiconductor structure and a preparation method therefor, for reducing the size of the semiconductor structure and improving the performance of the semiconductor structure.

In order to achieve the above objectives, the embodiments of the present application provide the following technical solutions.

A first aspect of the embodiments of the present application provides a semiconductor structure, including a substrate, a source layer, a drain layer, a channel layer, a gate structure, a gate dielectric layer, and a dielectric layer. The source layer and the drain layer are stacked disposed on the substrate. The channel layer is located between the source layer and the drain layer. The gate structure is located on a side wall of the channel layer. The gate dielectric layer is located between the gate structure and the channel layer. A portion of the dielectric layer is arranged between the source layer and the gate structure. The source layer has a plurality of depressions extending towards the substrate, and the channel layer is partially filled into the depressions and electrically connected to the source layer.

In some optional embodiments, the semiconductor structure further includes a fill layer located between the channel layer and the drain layer, and filled into the depression.

In some optional embodiments, the contour shape of the depression is arc-shaped or U-shaped.

In some optional embodiments, the fill layer includes a first portion and a second portion, the first portion is located above and in contact with the second portion, and a maximum width W2 of the second portion is smaller than a maximum width W1 of the first portion.

In some optional embodiments, the fill layer further includes a third portion, the second portion is located between the first portion and the third portion, and a maximum width W3 of the third portion is greater than the maximum width W2 of the second portion.

In some optional embodiments, the maximum width W3 of the third portion is smaller than the maximum width W1 of the first portion.

In some optional embodiments, the gate dielectric layer includes a first dielectric portion and a second dielectric portion connected to each other, and the second dielectric portion is in direct contact with the channel layer.

In some optional embodiments, the second dielectric portion is in direct contact with the source layer.

In some optional embodiments, the second dielectric portion is located above the source layer, and a portion of the dielectric layer is located between the second dielectric portion and the source layer.

In some optional embodiments, the gate dielectric layer has an L-shaped contour.

In some optional embodiments, the semiconductor structure further includes a sacrificial layer located between the gate dielectric layer and the channel layer, and the sacrificial layer has an L-shaped contour.

In some optional embodiments, a side wall of the first dielectric portion is in direct contact with the dielectric layer.

A second aspect of the embodiments of the present application further provides a preparation method of a semiconductor structure, including:
providing a substrate and forming a source layer on the substrate;
forming a dielectric layer on the source layer and forming a gate structure in the dielectric layer;
forming a gate dielectric layer on a side wall of the gate structure;
forming a depression extending towards a side of the substrate on the source layer, and forming a channel layer and making a portion of the channel layer fill into the depression, where the channel layer is electrically connected to the source layer; and
forming a drain layer on the channel layer.

In some optional embodiments, the method for forming the gate dielectric layer and the gate structure includes:
forming a plurality of initial gates on the dielectric layer, where the plurality of initial gates are arranged on the dielectric layer at intervals along a horizontal direction, and forming an isolation structure between the adjacent initial gates;
forming a first opening extending along a vertical direction in the initial gates, where the first opening penetrates a side of the dielectric layer away from the source layer, the source layer being not exposed by the first opening, and forming the retained initial gates as the gate structure; and
forming the gate dielectric layer on the first opening.

In some optional embodiments, the method for forming the depression on the source layer and forming the channel layer includes:
removing a portion of the dielectric layer and a portion of the source layer to form a through-hole that runs through the dielectric layer at the center of the gate dielectric layer;
removing a portion of the source layer along an etching direction of the through-hole to form a depression connected to the through-hole on the source layer; and
forming the channel layer on exposed surfaces of the through-hole and the depression.

In the semiconductor structure provided by the embodiments of the present application, on the one hand, a source layer and a drain layer are stacked on a substrate, a channel layer is located between the source layer and the drain layer, a gate structure is located on a side wall of the channel layer, a gate dielectric layer is located between the gate structure and the channel layer, and a portion of the dielectric layer is arranged between the source layer and the gate structure, in this way, the space of the semiconductor structure in a vertical direction may be effectively utilized to achieve the purpose of size reduction. On the other hand, the source layer is provided with a depression extending towards a side of the substrate, and the channel layer is partially filled into the depression and electrically connected to the source layer, so as to further reduce the size of the semiconductor structure and meantime improve the conductivity reliability between the channel layer and the source layer, thereby ensuring the performance of the semiconductor structure.

### BRIEF DESCRIPTION OF THE DRAWINGS

In order to illustrate the technical solutions in the embodiments of the present application clearly, the drawings required in the description of the embodiments will be briefly introduced below. Obviously, the drawings in the following description are only some embodiments of the present application. For the person skilled in the art, other drawings may also be obtained based on these drawings without creative work.

FIG. 1 is a structural schematic diagram of a semiconductor structure provided by an embodiment of the present application.

FIG. 2 is another structural schematic diagram of a semiconductor structure provided by an embodiment of the present application.

FIG. 3 is yet another structural schematic diagram of a semiconductor structure provided by an embodiment of the present application.

FIG. 4 is a flowchart of the preparation of the semiconductor structure provided by an embodiment of the present application.

FIG. 5 to FIG. 16 are schematic diagrams of the preparation process for preparing the semiconductor structure provided in FIG. 1.

FIG. 17 to FIG. 20 are schematic diagrams of the preparation process for preparing the semiconductor structure provided in FIG. 2 based on the structure of FIG. 10.

### DESCRIPTION OF EMBODIMENTS

With the development of semiconductor technologies, semiconductor integrated circuits are more inclined towards small-sized design and high-density layout. For semiconductor structures with smaller and smaller size, it is increasingly difficult to further reduce size and ensure the performance of the semiconductor structures.

In view of this, a semiconductor structure is provided by the embodiments of present application. On the one hand, a source layer and a drain layer are stacked on a substrate, a channel layer is located between the source layer and the drain layer, a gate structure is located on a side wall of the channel layer, a gate dielectric layer is located between the gate structure and the channel layer, and a portion of the dielectric layer is arranged between the source layer and the gate structure. In this way, the space of the semiconductor structure in a vertical direction may be effectively utilized to achieve the purpose of size reduction. On the other hand, the source layer is provided with a depression extending towards a side of the substrate, and the channel layer is partially filled into the depression and electrically connected to the source layer, so as to further reduce the size of the semiconductor structure and meantime improve the conductivity reliability between the channel layer and the source layer, thereby ensuring the performance of the semiconductor structure.

In order to make the above objectives, features, and advantages of the embodiments of the present application more obvious and understandable, the technical solutions in the embodiments of the present application will be clearly and completely described below in combination with the drawings in the embodiments of the present application. Obviously, the described embodiments are a part of the embodiments of the present application, but not limited thereto. Based on the embodiments in the present application, all other embodiments obtained by the person skilled in the art without creative work fall within the protection scope of the present application.

### Embodiment 1

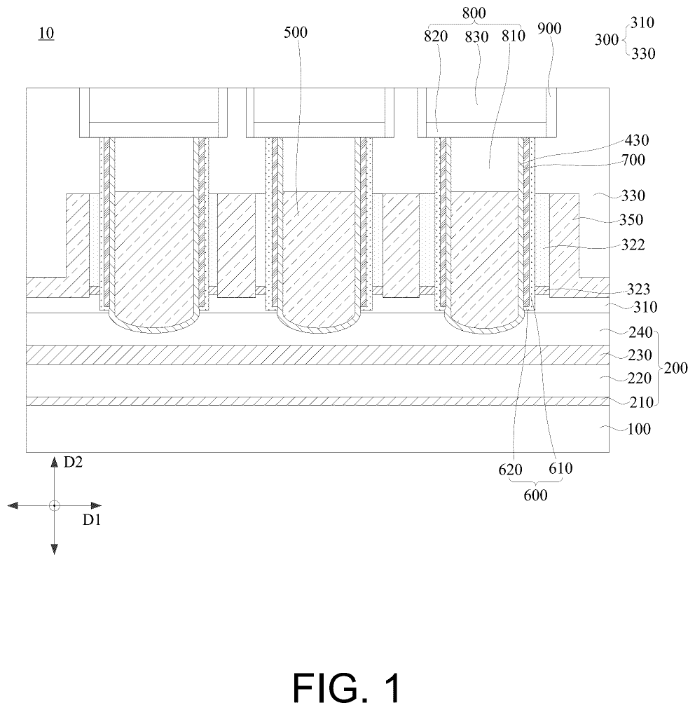

FIG. 1 is a structural schematic diagram of a semiconductor structure provided by an embodiment of the present application. An embodiment of the present application provides a semiconductor structure. As shown in FIG. 1, the semiconductor structure 10 includes a substrate 100, a source layer 200, a drain layer 800, a channel layer 430, a gate structure 322, a gate dielectric layer 600, and a dielectric layer 300. The source layer 200 and the drain layer 800 are stacked disposed on the substrate. The channel layer 430 is located between the source layer 200 and the drain layer 800, and is electrically connected to the source layer 200 and the drain layer 800. The gate structure 322 is located on the sidewall of the channel layer 430. The gate dielectric layer 600 is located between the gate structure 322 and the channel layer 430. A portion of the dielectric layer 300 is arranged between the source layer 200 and the gate structure 322. The substrate 100 can provide support for the source layer 200, the drain layer 800, the channel layer 430, the gate structure 322, the gate dielectric layer 600, the dielectric layer 300 and etc.

In an embodiment of the present application, the source layer 200 and the drain layer 800 are stacked on the substrate 100, the channel layer 430 is located between the source layer 200 and the drain layer 800, the gate structure 322 is located on the side wall of the channel layer 430, the gate dielectric layer 600 is located between the gate structure 322 and the channel layer 430, and a portion of the dielectric layer 300 is arranged between the source layer 200 and the gate structure 322. In this way, the space of the semiconductor structure 10 in a vertical direction may be effectively utilized to achieve the purpose of size reduction.

As shown in FIG. 1, the drain layer 800, the portion of the channel layer 430, the gate structure 322 and the gate dielectric layer 600 are located in the dielectric layer 300. For example, the drain layer 800, the portion of the channel layer 430, the gate structure 322 and the gate dielectric layer 600 are embedded in the dielectric layer 300. In this way, the spatial utilization of the semiconductor structure 10 in a vertical direction D2 may be further improved, thereby achieving the purpose of reducing the size of the semiconductor structure 10 and ensuring the performance of the semiconductor structure 10.

It should be noted that the source layer 200 and the drain layer 800 being stacked disposed on the substrate 100 refers to that the source layer 200 and the drain layer 800 are arranged on the substrate 100, and are stacked along the direction perpendicular to the substrate 100 (as shown in the vertical direction D2 in FIG. 1). For example, the source layer 200 is located above the substrate 100 along the vertical direction D2, and the drain layer 800 is located above the source layer 200; and the source layer 200 includes but is not limited to direct contact with the substrate 100, that is, the source layer 200 may be directly arranged on the substrate 100, or other structural layers may be arranged between the source layer 200 and the substrate 100; the drain layer 800 is located above the source layer 200 but does not come into direct contact with the source layer 200.

In some embodiments, both the source layer 200 and the drain layer 800 may be a single-layer structure or a composite structure. Exemplarily, at least one of the source layer 200 and the drain layer 800 may be a composite structure. For example, in FIG. 1, the source layer 200 includes a first blocking layer 210, a first conductive layer 220, a second blocking layer 230 and a first semiconductor layer 240 which are stacked sequentially on the substrate 100, where the first blocking layer 210 is in direct contact with the substrate 100; the drain layer 800 includes a second semiconductor layer 810, a third blocking layer 820 and a second conductive layer 830 which are stacked sequentially, where the second semiconductor layer 810 is located on a side near the source layer 200, and the third blocking layer 820 is located between the second semiconductor layer 810 and the second conductive layer 830.

The first blocking layer 210, the second blocking layer 230, and the third blocking layer 820 may be metal nitride layers. For example, the materials of the first blocking layer 210, the second blocking layer 230 and the third blocking layer 820 may include but are not limited to titanium nitride (TiN), tantalum nitride, or other suitable conductive barrier materials. The material composition of the first blocking layer 210, the second blocking layer 230 and the third blocking layer 820 may be the same or different. In addition, the first conductive layer 220 and the second conductive layer 830 may be conductive metal layers. For example, the materials of the first conductive layer 220 and the second conductive layer 830 include but are not limited to conductive materials with low resistivity such as tungsten, copper, aluminum, etc. The material composition of the first conductive layer 220 and the second conductive layer 830 may be the same or different. The materials of which the first semiconductor layer 240 and the second semiconductor layer 810 may be made include silicon-contained semiconductor materials (for example, include but are not limited to polycrystalline silicon semiconductor materials or amorphous silicon semiconductor materials), oxide semiconductor materials (for example, include but are not limited to indium gallium zinc oxide semiconductor materials), or other suitable semiconductor materials, and the material composition of the first semiconductor layer 240 and the second semiconductor layer 810 may be the same or different.

It can be understood that in an embodiment of the present application, the first semiconductor layer 240 is included in the source layer 200 and the second semiconductor layer 810 is included in the drain layer 800, thereby the overall performance of the semiconductor structure 10 is improved.

In addition, in an embodiment of the present application, the source layer 200 has a plurality of depressions 410 extending towards a side of the substrate 100, and the channel layer 430 is partially filled into the depressions 410. In this way, the contact area between the channel layer 430 and the source layer 200 is increased and the conductivity reliability between the channel layer 430 and the source layer 200 is improved, thereby ensuring the performance of the semiconductor structure 10.

Exemplarily, in FIG. 1, a depression 410 is located on the first semiconductor layer 240 in the source layer 200, that is, a side of the first semiconductor layer 240 away from the substrate 100 has a depression 410 extending towards a side of the substrate 100.

In some embodiments, a contour shape of the depression 410 may be either arc-shaped or U-shaped. For example, the contour shape of depression 410 is a structure of circular arc, an elliptical arc and other arcs, or a structure of U-shape.

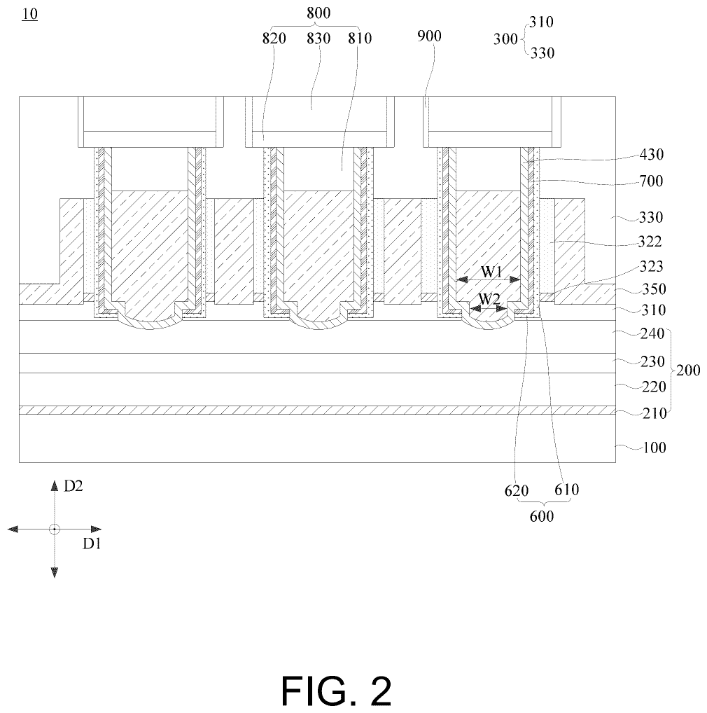

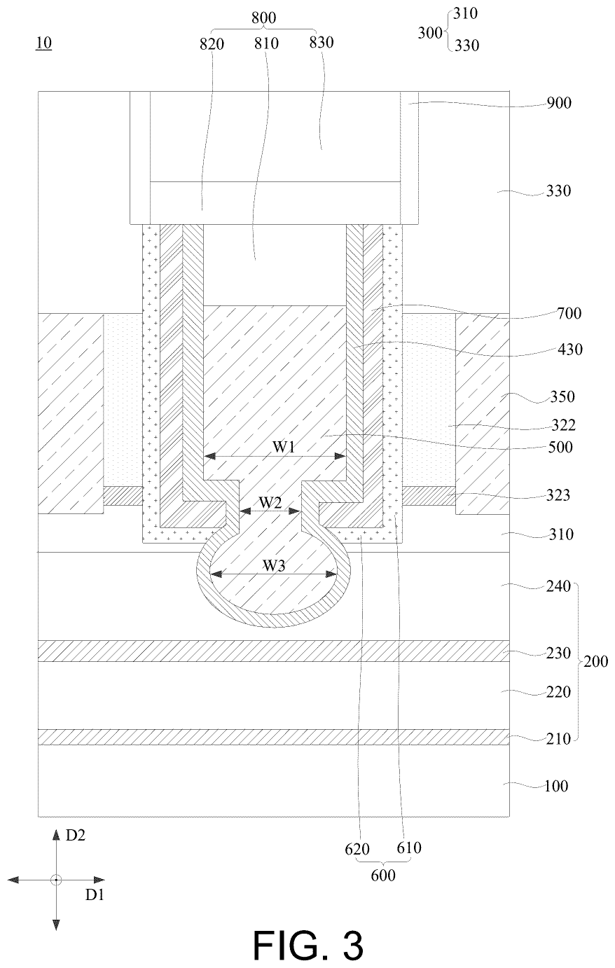

For an exemplary example, as shown in FIG. 1 and FIG. 3, the contour shape of the depression 410 is arc-shaped. For another exemplary example, as shown in FIG. 2, the contour shape of the depression 410 is U-shaped. The contour shape and size of the depression 410 may be adaptively designed according to actual needs, and which is not limited here.

In addition, the contour shape of the channel layer 430 which is partially filled into the depression 410 matches the contour shape of the depression 410 so as to increase the conductivity reliability of the channel layer 430 and the source layer 200, thereby improving the overall performance of the semiconductor structure 10.

In some embodiments, the semiconductor structure 10 further includes a fill layer 500, which is located between the channel layer 430 and the drain layer 800, and is partially filled into the depression 410 so as to achieve electrical isolation between the source layer 200 and the drain layer 800 through the fill layer 500. Exemplarily, as shown in FIG. 1, the fill layer 500 is located above the channel layer 430 and at least partially filled into the depression 410, and the drain layer 800 is arranged above the fill layer 500. The fill layer 500 is made of insulating material, and an isolation between the source layer 200 and the drain layer 800 in a vertical direction D2 is achieved through the fill layer 500, so that current may flow in the channel layer 430 located between the drain layer 800 and the source layer 200. The contour shape of the fill layer 500 matches the contour shape of the channel layer 430.

It should be noted that the contour shape of the depression 410 may be made according to actual needs or different processes. The depression 410 is formed with different contour shapes, a matching channel layer 430 is arranged on the depression 410, and then a fill layer 500 with a contour shape that matches the contour shape of the channel layer 430 is arranged on the channel layer 430, thereby semiconductor structures 10 with different structures are formed to meet different performance requirements.

The fill layer 500 may be made of an oxide layer, for example, the material of the fill layer 500 includes but is not limited to a layer of silicon oxide or other suitable insulating materials.

For an exemplary example, as shown in FIG. 1, the contour shape of the channel layer 430 is U-shaped, and correspondingly, the contour shape of the fill layer 500 is U-shaped.

FIG. 2 is another structural schematic diagram of a semiconductor structure provided by an embodiment of the present application. FIG. 3 is yet another structural schematic diagram of a semiconductor structure provided by an embodiment of the present application.

For another exemplary example, as shown in FIG. 2 and FIG. 3, the fill layer 500 includes a first portion and a second portion, the first portion is located above and in contact with the second portion, and the maximum width W2 of the second portion is smaller than the maximum width W1 of the first portion.

In some embodiments, please continue to refer to FIG. 3, the fill layer 500 further includes a third portion, which is located on the side of the second portion away from the first portion, that is, the second portion is located between the first portion and the third portion; and a part of the third portion is filled into the depression 410.

Exemplarily, in FIG. 2, the maximum width of the third portion is equal to the maximum width W2 of the second portion; in FIG. 3, the maximum width W3 of the third portion is greater than the maximum width W2 of the second portion.

In some embodiments, as shown in FIG. 2 and FIG. 3, the maximum width W3 of the third portion is smaller than the maximum width W1 of the first portion.

In some embodiments, please continue to refer to FIG. 1 to FIG. 3, the gate dielectric layer 600 includes a first dielectric portion 610 and a second dielectric portion 620 which are connected to each other, and the second dielectric portion 620 is in direct contact with the channel layer 430.

Exemplarily, an oblique angle is formed between the first dielectric portion 610 and the second dielectric portion 620. For example, in FIG. 1 and FIG. 3, the first dielectric portion 610 and the second dielectric portion 620 are perpendicular or approximately perpendicular to each other, and the second dielectric portion 620 extends in a horizontal direction (such as horizontal direction D1) or an approximately horizontal direction. In addition, an end of the second dielectric portion 620 is in direct contact with the sidewall of the channel layer 430, the other end of the second dielectric portion 620 is connected to the first dielectric portion 610, and the first dielectric portion 610 extends along the vertical direction D2. The first dielectric portion 610 is located between the gate structure 322 and the channel layer 430.

In some embodiments, the second dielectric portion 620 may be in direct contact with the source layer 200, or an isolation structure 350, such as a dielectric layer 300, may be arranged between the second dielectric portion 620 and the source layer 200.

For an exemplary example, in FIG. 1, the second dielectric portion 620 is located above the source layer 200 and in direct contact with the source layer 200, so that the overall performance of the semiconductor structure 10 is improved. In addition, the dielectric layer 300 is in direct contact with a portion of the side wall of the first dielectric portion 610, for example, the dielectric layer 300 is in direct contact with the side wall of the first dielectric portion 610 near an end of the source layer 200.

For another exemplary example, in FIG. 2 and FIG. 3, the second dielectric portion 620 is located above the source layer 200, and a portion of the dielectric layer 300 is arranged between the second dielectric portion 620 and the source layer 200, that is, the dielectric layer 300 is in direct contact with the bottom surface of the second dielectric portion 620. In addition, the dielectric layer 300 is further in direct contact with a portion of the side wall of the first dielectric portion 610, for example, the dielectric layer 300 is in direct contact with a portion of the side wall of the first dielectric portion 610 near an end of the source layer 200.

In some embodiments, please refer to FIG. 1 to FIG. 3, the gate dielectric layer 600 has an L-shaped contour, and the gate dielectric layer 600 is located between the channel layer 430 and the gate structure 322. In addition, an end of the gate dielectric layer 600 is in direct contact with the channel layer 430, and the gate structure 322 is arranged on the side wall of a side of the gate dielectric layer 600 away from the channel layer 430.

The materials of which the gate dielectric layer 600 may be made include oxide dielectric materials (for example, include but are not limited to silicon oxide), nitride dielectric materials (for example, include but are not limited to silicon nitride), high dielectric constant dielectric materials (for example, dielectric materials with a dielectric constant higher than 3.9 or a dielectric constant higher than 4.52), or other suitable dielectric materials.

In some embodiments, please continue to refer to FIG. 1 to FIG. 3, the semiconductor structure 10 further includes a sacrificial layer 700 between the gate dielectric layer 600 and the channel layer 430, that is, the sacrificial layer 700 is located between the gate dielectric layer 600 and the channel layer 430.

Exemplarily, as shown in FIG. 2 and FIG. 3, the contour shape of the sacrificial layer 700 matches the contour shape of the gate dielectric layer 600. For example, when the contour of the gate dielectric layer 600 is an L-shaped contour, the sacrificial layer 700 having an L-shaped contour matches the gate dielectric layer 600.

It can be understood that by arranging a sacrificial layer 700 between the channel layer 430 and the gate dielectric layer 600, it is able to avoid the reaction between the gate dielectric layer 600 and the conductive materials of the channel layer 430 which may result in high resistance products and thus affect the flow efficiency of current in the channel layer 430, thereby improving the overall performance of the semiconductor structure 10.

The materials of which the sacrificial layer 700 may be made, for example, are silicides. For example, the sacrificial layer 700 includes silica or other suitable sacrificial materials.

In some embodiments, an isolation structure 350 is arranged on the side wall of a side of the gate structure 322 away from the gate dielectric layer 600. The materials of which the isolation structure 350 may be made include but are not limited to oxide materials. For example, the isolation structure 350 is made of silicon oxide and the like. As long as the electrical isolation between adjacent gate structures 322 can be achieved, there is no limitation here.

In addition, an insulation layer 900 is arranged on the side walls of a third blocking layer 820 and a second conductive layer 830 to achieve electrical isolation between adjacent drain layers 800. The materials of which the insulation layer 900 is formed, for example, are oxides or other suitable insulation materials.

Please continue to refer to FIG. 1, the top surface of the insulation layer 900 is flush with a surface of the dielectric layer 300 and a surface of the second conductive layer 830 respectively. The insulation layer 900 is located between the side wall of the second conductive layer 830 and the dielectric layer 300 so as to ensure the overall performance of the semiconductor structure 10.

In addition, a projection of the second conductive layer 830 in the vertical direction D2 covers a projection of the second semiconductor layer 810 in the vertical direction D2. Exemplarily, as shown in FIG. 1, the projection area of the second conductive layer 830 in the vertical direction D2 is larger than that of the second semiconductor layer 810 in the vertical direction D2.

### Embodiment 2

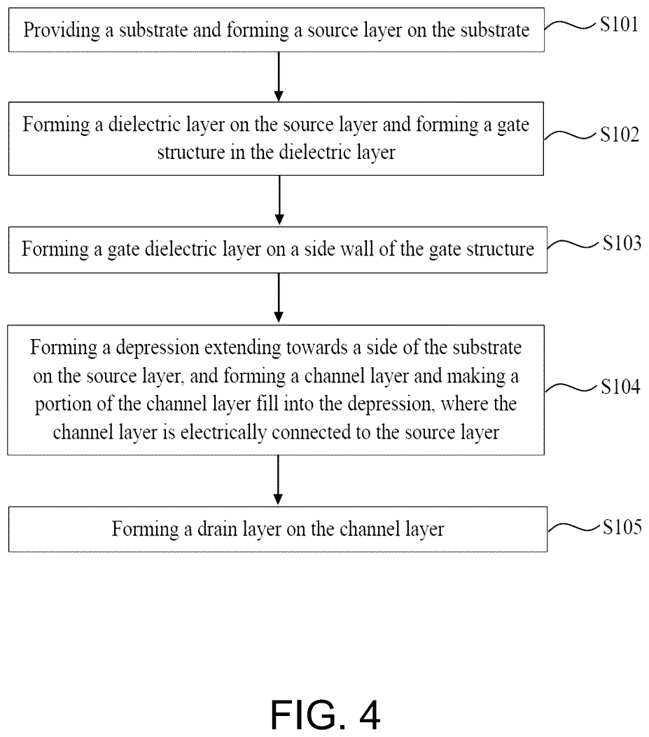

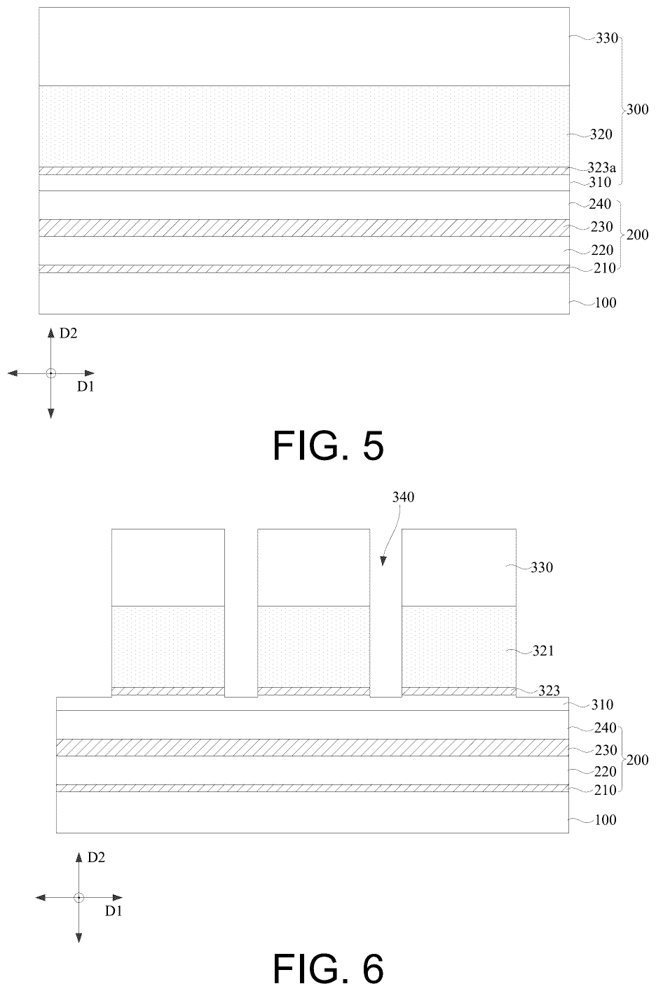

FIG. 4 is a flowchart of the preparation of the semiconductor structure provided by an embodiment of the present application; FIG. 5 to FIG. 16 are schematic diagrams of the preparation process for preparing the semiconductor structure provided in FIG. 1.

Please refer to FIG. 4, a preparation method for a semiconductor structure is provided by an embodiment of the present application, and the preparation method includes the following.
Step S101: providing a substrate and forming a source layer on the substrate.
Step S102: forming a dielectric layer on the source layer and forming a gate structure in the dielectric layer.
Step S103: forming a gate dielectric layer on a side wall of the gate structure.
Step S104: forming a depression extending towards a side of the substrate on the source layer, forming a channel layer and making a portion of the channel layer fill into the depression, where the channel layer is electrically connected to the source layer.
Step S105: forming a drain layer on the channel layer.

In the specific implementation, please refer to FIG. 5. Firstly, providing a substrate 100. The substrate 100 may be prepared and formed by chemical vapor deposition (CVD) process.

The materials constituting the substrate 100 may include any one or more of silicon, germanium, germanium silicon, silicon carbide, silicon on insulator, and germanium on insulator. Alternatively, the materials constituting the substrate 100 may also be other materials known to the person skilled in the art. In an embodiment of the present application, at least a portion of the substrate 100 is a silicon substrate 100, and the silicon material may be monocrystalline silicon.

After the substrate 100 is formed, processes such as chemical vapor deposition, physical vapor deposition (PVD), or atomic layer deposition (ALD) may be used to form a source layer 200 on the substrate 100.

In some embodiments, the source layer 200 may be a single-layer structure or a composite structure. Exemplarily, as shown in FIG. 5, the source layer 200 is a composite structure, that is, the source layer 200 includes a first blocking layer 210 formed on the substrate 100, a first conductive layer 220 formed on the first blocking layer 210, a second blocking layer 230 formed on the first conductive layer 220, and a first semiconductor layer 240 formed on the second blocking layer 230. In this way, the first blocking layer 210, the first conductive layer 220, the second blocking layer 230 and the first semiconductor layer 240 which are sequentially stacked, are formed together as the source layer 200.

Each layer in the source layer 200 may be formed through chemical vapor deposition process, physical vapor deposition process, atomic layer deposition process or other suitable formation processes. The specific selection may be made according to actual needs, and there is no limitation here.

It can be understood that by arranging a first blocking layer 210 between the first conductive layer 220 and the substrate 100, and arranging a second blocking layer 230 between the first conductive layer 220 and the first semiconductor layer 240, it is able to avoid material reactions between the conductive material and the substrate 100 as well as the first semiconductor layer 240 which may result in the formation of high resistance reaction products. In addition, by forming a first semiconductor layer 240 in the source layer 200, the overall performance of the semiconductor structure 10 may be improved and the operational reliability of the semiconductor device may be improved.

In some embodiments, the materials of which the first blocking layer 210 and the second blocking layer 230 are made may be materials such as metal nitrides, and the materials of which the first conductive layer 220 is made may be, for example, conductive metal materials. The materials of which the first semiconductor layer 240 is made may be, for example, silicon-contained semiconductor materials.

Exemplarily, in FIG. 5, the materials of which the first blocking layer 210 and the second blocking layer 230 are made include but are not limited to titanium nitride (TiN), the first conductive layer 220 includes but is not limited to metal tungsten, and the first semiconductor layer 240 includes but is not limited to a polycrystalline silicon semiconductor layer and the like.

In some embodiments, after the source layer 200 is formed on the substrate 100, a dielectric layer 300 is formed on the source layer 200. Please continue to refer to FIG. 5, when forming a dielectric layer 300 on the source layer 200, firstly, the first dielectric layer 310 may be formed on the source layer 200 through a deposition process. After the first dielectric layer 310 is formed, a fourth initial blocking layer 323a is deposited on the first dielectric layer 310, and a gate layer 320 is deposited on the fourth initial blocking layer 323a. Then, a second dielectric layer 330 is deposited on the gate layer 320, and the fourth initial blocking layer 323a and the gate layer 320 are embedded in the dielectric layer 300.

Please refer to FIG. 6, after the dielectric layer 300 is formed on the source layer 200 and the fourth initial blocking layer 323a and the gate layer 320 are formed in the dielectric layer 300, a portion of the second dielectric layer 330, the gate layer 320, the fourth initial blocking layer 323a and a portion of the first dielectric layer 310 are sequentially removed along the vertical direction D2 through wet etching process, dry etching process or other suitable etching processes. A plurality of trenches 340 are formed on the first dielectric layer 310. The gate layer 320 retained in the dielectric layer 300 is formed as the initial gate structure 321, and the initial fourth blocking layer 323 retained in the dielectric layer 300 is formed as the fourth blocking layer 323.

It should be noted that as shown in FIG. 6, there is a portion of the first dielectric layer 310 between the trench 340 and the source layer 200, and the trench 340 runs through the dielectric layer 300 along the vertical direction D2 towards one end away from the source layer 200.

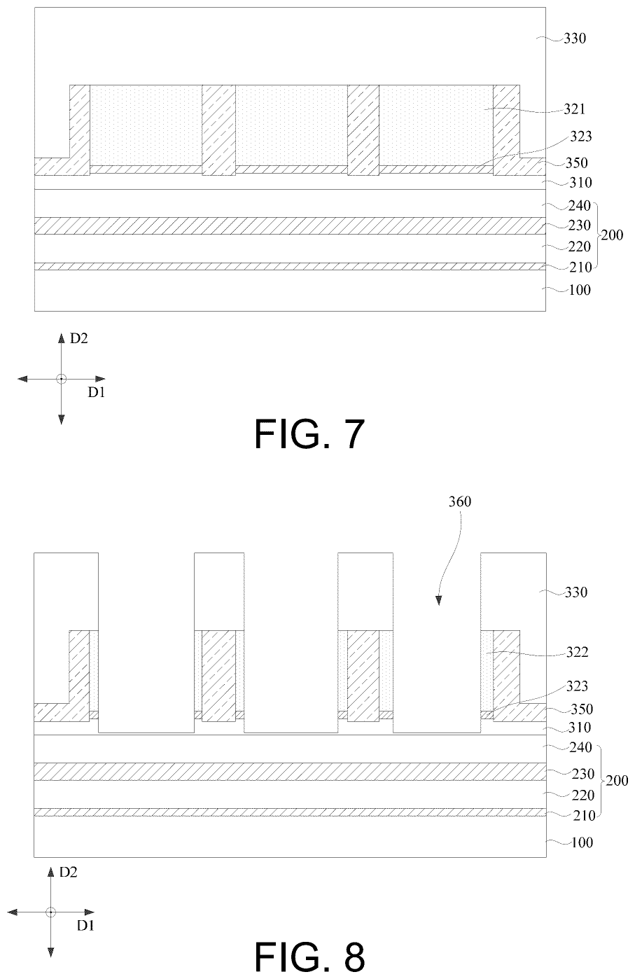

Please refer to FIG. 7, after the plurality of trenches 340 are formed on the dielectric layer 300, the isolation material is filled in the trench 340 to form an isolation structure 350, so that the isolation structure 350 is located between adjacent initial gate structures 321 to electrically isolate the adjacent gate structures 322. In addition, after the isolation structure 350 is formed in the trench 340, the dielectric materials are deposited on the surface of the isolation structure 350 and the initial gate structure 321 to form a second dielectric layer 330, and the second dielectric layer 330 covers the surfaces of the isolation structure 350 and the initial gate structure 321.

Please refer to FIG. 8, after the initial gate structure 321 and the isolation structure 350 between adjacent initial gate structures 321 are formed, a portion of the second dielectric layer 330, the initial gate structure 321, the fourth blocking layer 323, and the first dielectric layer 310 are removed continuously along the vertical direction D2 through wet etching, dry etching, or other suitable etching processes. Forming a first opening 360 on the dielectric layer 300, so that the initial gate structures 321 retained on the opposite walls of the first opening 360 is formed as the gate structure 322.

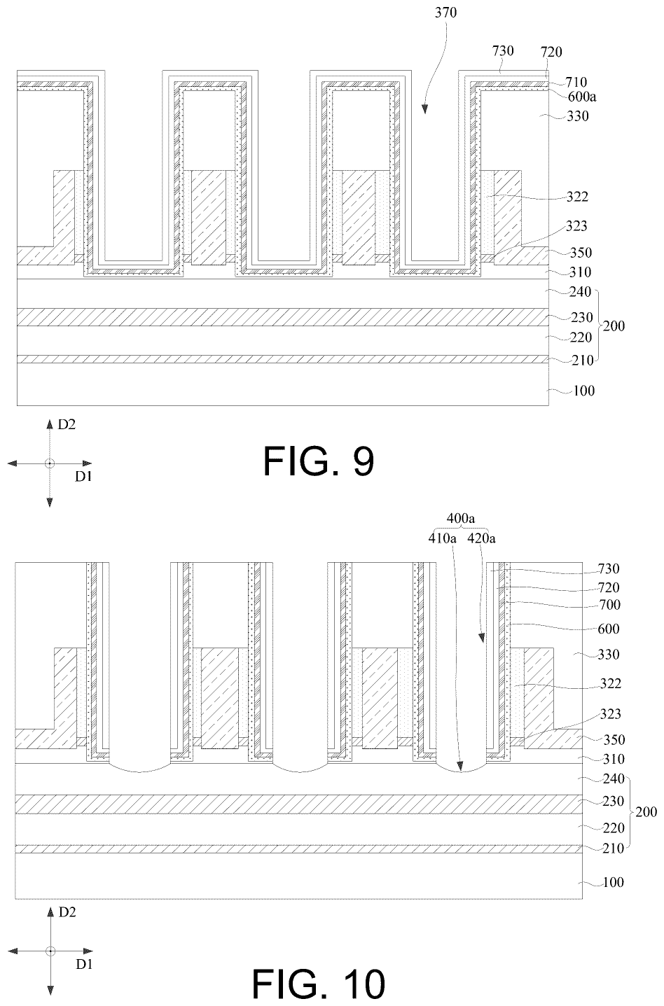

Please refer to FIG. 9, after the first opening 360 is formed on the dielectric layer 300, an initial gate dielectric layer 600a, a first initial sacrificial layer 710, a second initial sacrificial layer 720 and a third initial sacrificial layer 730 are sequentially formed on the exposed surface of the first opening 360 through chemical vapor deposition process, physical vapor deposition process, atomic layer deposition process, or other suitable deposition processes. The initial gate dielectric layer 600a covers the surface of the first opening 360 and the surface of the exposed dielectric layer 300. The first initial sacrificial layer 710 is stacked above the initial gate dielectric layer 600a, and the second initial sacrificial layer 720 is stacked above the first initial sacrificial layer 710, the third initial sacrificial layer 730 is stacked above the second initial sacrificial layer 720, and the third initial sacrifice layer 730 is enclosed in the first opening 360 to form the second opening 370.

Please refer to FIG. 10, after the second opening 370 is formed on the dielectric layer 300, the third initial sacrificial layer 730, the second initial sacrificial layer 720, the first initial sacrificial layer 710, and the initial gate dielectric layer 600a on the surface of the dielectric layer 300 are sequentially removed through processes such as chemical mechanical polishing, while the initial gate dielectric layer 600a, the first initial sacrificial layer 710, the second initial sacrificial layer 720, and the third initial sacrificial layer 730 in the first opening 360 are retained. Afterwards, along the vertical direction D2 of the second opening 370, the third initial sacrificial layer 730, the second initial sacrificial layer 720, the first initial sacrificial layer 710 and the initial gate dielectric layer 600a are sequentially removed from the bottom surface of the second opening 370 through dry etching or wet etching processes. Forming an initial through-hole 420a on the dielectric layer 300 and an initial depression 410a on the source layer 200, where the initial through-hole 420a and the initial depression 410a are jointly formed as an initial channel 400a (as shown in FIG. 10).

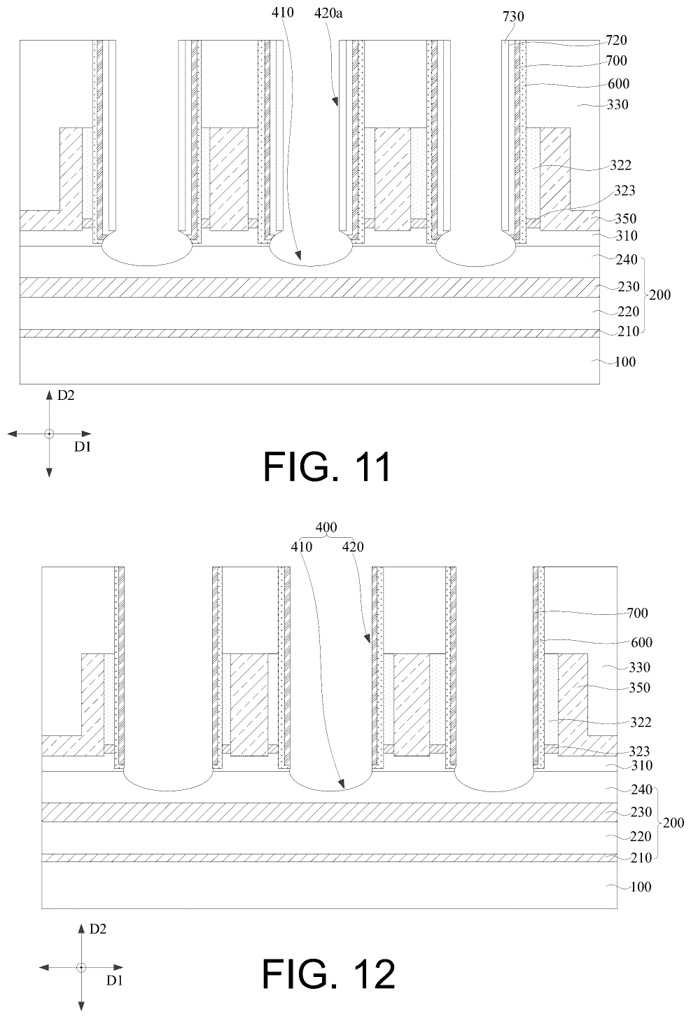

In some embodiments, please refer to FIG. 11, after the initial channel 400a is formed, the wet etching process is adopted to continue etching.

It should be noted that when the wet etching process is adopted to form a depression 410 on the source layer 200, a portion of the third initial sacrificial layer 730 and the second initial sacrificial layer 720 on the hole wall of the initial through-hole 420a near the source layer 200 is etched at same time, forming the structure shown in FIG. 11.

Please refer to FIG. 12, after the depression 410 is formed on the source layer 200, the third initial sacrificial layer 730 and the second initial sacrificial layer 720 on the hole wall of the initial through-hole 420a may be removed by using dry etching process, wet etching process, or other suitable etching processes, and the retained first initial sacrificial layer 710 is formed as sacrificial layer 700. In this way, in the dielectric layer 300, the sacrificial layer 700 is surrounded to form a through-hole 420, and the through-hole 420 and the depression 410 on the source layer 200 jointly form a channel 400; the initial gate dielectric layer 600a retained between the sacrificial layer 700 and the gate structure 322 forms the gate dielectric layer 600, so that the gate structure 322 is located on the side wall of a side of the gate dielectric layer 600 away from the sacrificial layer 700, and the gate dielectric layer 600 is located between the gate structure 322 and the sacrificial layer 700.

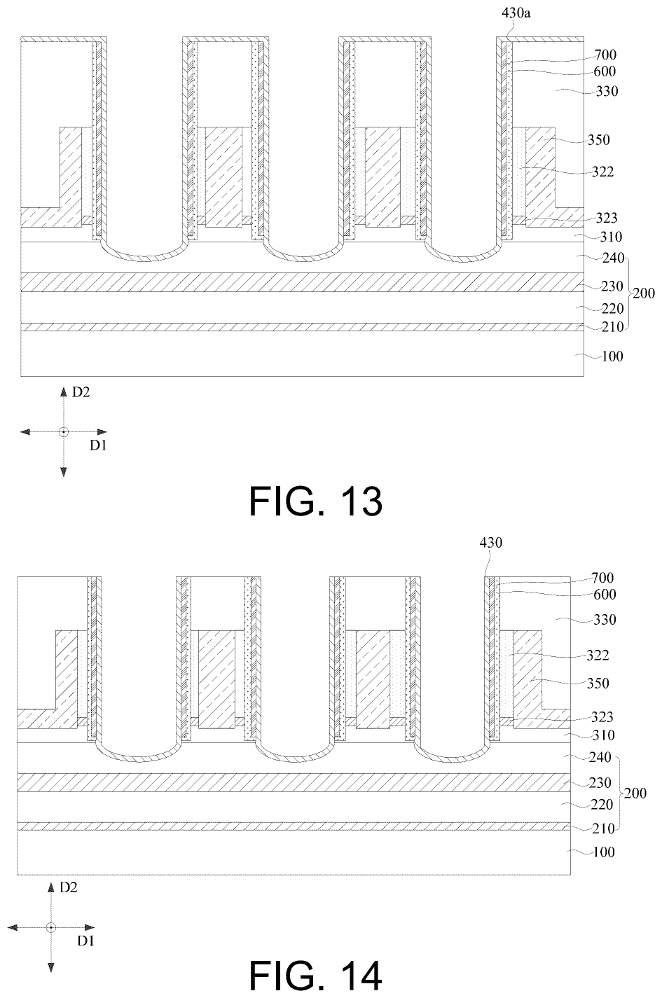

Please refer to FIG. 13, after the channel 400 is formed, channel 400 materials are deposited in the channel 400 to form an initial channel layer 430a in the channel 400. The channel 400 materials may be conductive materials such as tungsten, copper, aluminum, etc., or semiconductor materials such as polycrystalline silicon semiconductor materials or amorphous silicon semiconductor materials or other suitable materials for a channel layer 430. In this way, the initial channel layer 430a covers the surface of the channel 400 and the upper surface of the dielectric layer 300.

Please refer to FIG. 14, after the initial channel layer 430a is formed in the channel 400, the initial channel layer 430a on the upper surface of the dielectric layer 300 may be removed by chemical mechanical polishing process, so that the upper surface of the initial channel layer 430a retained in the channel 400 is flush with the upper surface of the dielectric layer 300, the upper surface of the sacrificial layer 700, and the upper surface of the gate dielectric layer 600. In this way, the initial channel layer 430a retained in the channel 400 is formed as the channel layer 430, which is electrically connected to the source layer 200.

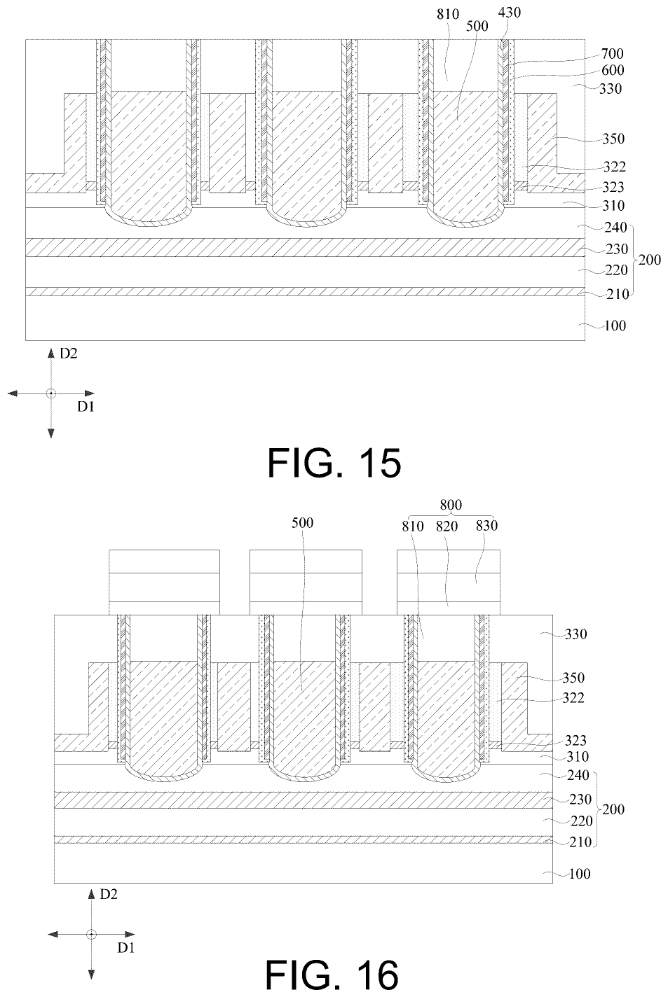

Please refer to FIG. 15, after the channel layer 430 is formed in the channel 400, insulating filling materials may be deposited on the channel layer 430 in the channel 400 through chemical vapor deposition process, physical vapor deposition process, or atomic layer deposition process to form a fill layer 500 on the channel layer 430, and a height of the fill layer 500 in the vertical direction D2 is less than a height of the channel 400. Afterwards, the semiconductor material is further deposited on the fill layer 500 in the channel 400 to form a second semiconductor layer 810, and the upper surface of the formed second semiconductor layer 810 is flush with the upper surface of the dielectric layer 300.

After the second semiconductor layer 810 is formed on the fill layer 500, a third initial blocking layer and a second initial conductive layer are sequentially formed on the upper surfaces of the dielectric layer 300 and the second semiconductor layer 810, and a mask layer is formed on the third initial blocking layer and the second initial conductive layer. The mask layer is patterned, and the patterned mask layer is used as a mask. A portion of the second initial conductive layer and a portion of the third initial blocking layer are sequentially removed along the vertical direction D2, and the third initial blocking layer and the second initial conductive layer above each second semiconductor layer 810 are retained. The retained third initial blocking layer is formed as a third blocking layer 820, and the retained second initial conductive layer is formed as a second conductive layer 830 (as shown in FIG. 16).

Afterwards, the mask layer above the second conductive layer 830 is removed, and an insulation layer 900 is formed on the side walls of the second conductive layer 830 and the third blocking layer 820. Then, the dielectric materials are deposited on the side wall of the insulation layer 900, and the upper surface of the dielectric layer 300 is flush with the upper surfaces of the second conductive layer 830 and the insulation layer 900. The semiconductor structure 10 formed is shown in FIG. 1. In this way, the second semiconductor layer 810, the second blocking layer 230, and the second conductive layer 830 jointly form a drain layer 800, and the channel layer 430 is electrically connected to the drain layer 800 and the source layer 200 respectively, so that a current between the source layer 200 and the drain layer 800 flows in the channel layer 430. In addition, the gate structure 322, the gate dielectric layer 600 and the channel layer 430 are arranged in a horizontal direction D1 in the dielectric layer 300. In this way, the space utilization ratio of the dielectric layer 300 in the horizontal direction D1 can be effectively utilized. The drain layer 800, the gate structure 322, the gate dielectric layer 600, the channel layer 430 and etc., are embedded in the dielectric layer 300, which may further improve the spatial utilization ratio of the dielectric layer 300 in the vertical direction D2, thereby reducing the overall size of the semiconductor structure 10. In addition, by forming a depression 410 on the source layer 200 and filling a portion of the channel layer 430 into the depression 410, the contact area between the channel layer 430 and the source layer 200 may be increased, thereby improving the overall performance of the semiconductor structure 10 and enhancing the functional reliability of the semiconductor device.

### Embodiment 3

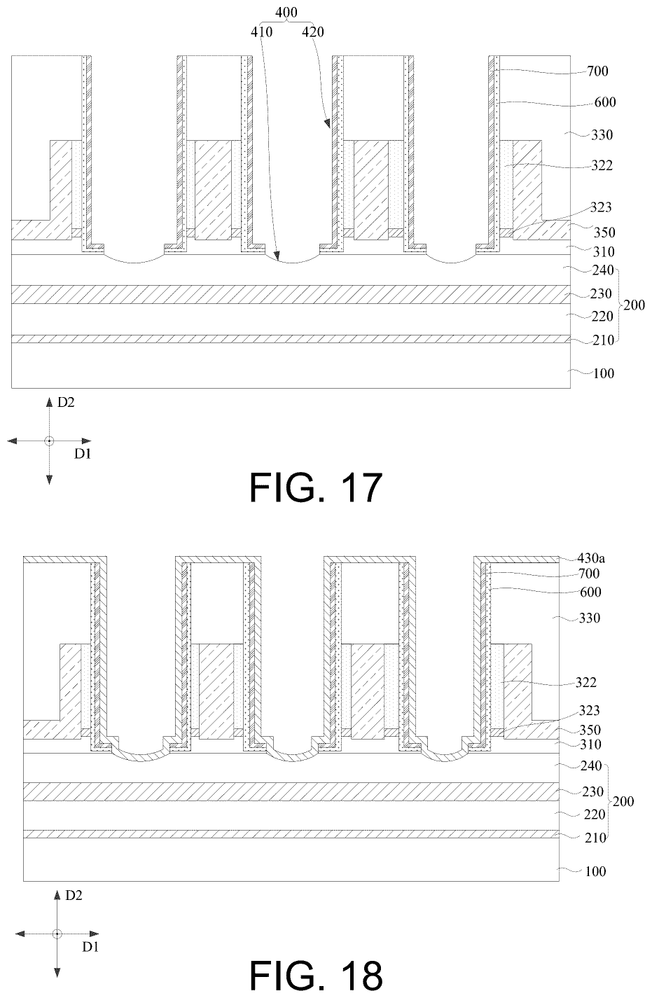

FIG. 17 to FIG. 20 are schematic diagrams of the preparation process for preparing the semiconductor structure provided in FIG. 2 based on the structure of FIG. 10.

The difference between the preparation method of the semiconductor structure provided in the present embodiment and the preparation method of the semiconductor structure provided in the Embodiment 2 only lies in that, the contour shape of the channel formed by different preparation processes based on the structure in FIG. 10 is different from the contour shape of the channel in the Embodiment 2 mentioned above. Other structures and preparation processes may be referred to the Embodiment 2 mentioned above. Only the contents different from the above-mentioned Embodiment 2 are explained here, and the same parts are not be repeated here.

Specifically, based on the structure in FIG. 10, after the initial through-hole 420a is formed on the dielectric layer 300 and the initial depression 410a is formed on the source layer 200, as shown in FIG. 17, in the embodiments of the present application, the third initial sacrificial layer 730 and the second initial sacrificial layer 720 in the initial through-hole 420a may be removed by wet etching process, dry etching process, or other suitable etching processes. The retained first initial sacrificial layer 710 is formed as a sacrificial layer 700, and the retained initial gate dielectric layer 600a is formed as a gate dielectric layer 600. The gate dielectric layer 600 is located between the sacrificial layer 700 and the gate structure 322.

As shown in FIG. 17, after the third sacrificial layer 700 and the second sacrificial layer 700 are removed, the initial through-hole 420a is formed as a through-hole 420, and a depression 410 is formed on the source layer 200. Since the through-hole 420 is formed after removing the third initial sacrificial layer 730 and the second initial sacrificial layer 720 from the hole wall of the initial through-hole 420a, the maximum width of the through-hole 420 is greater than the maximum width of the initial through-hole 420a. The depression 410 on the source layer 200 is formed by etching along the vertical direction D2 on the basis of the initial through-hole 420a, thus, the maximum width of the depression 410 formed on the source layer 200 is smaller than the maximum width of the through-hole 420. In this way, the depression 410 on the source layer 200 and the through-hole 420 in the dielectric layer 300 penetrate each other and jointly form a channel 400.

Please refer to FIG. 18, after the channel 400 is formed, the channel 400 materials are deposited through a deposition process in the channel 400 to form an initial channel layer 430a, which covers the surface of the channel 400 and the surface of the dielectric layer 300.

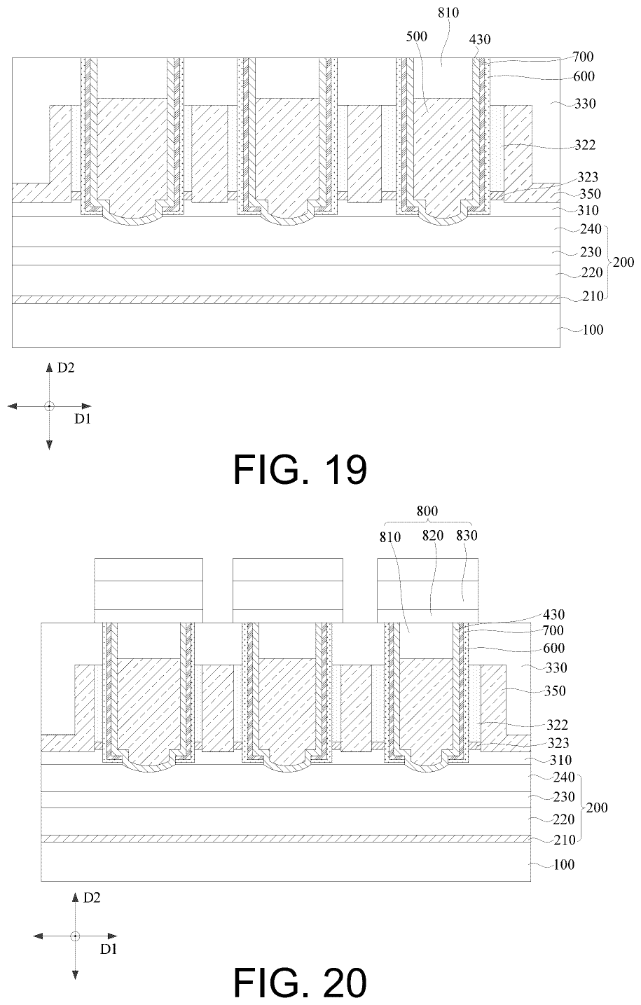

Please refer to FIG. 19, after the initial channel layer 430a is formed in the channel 400, the initial channel layer 430a covering on the surface of the dielectric layer 300 may be removed using a chemical mechanical polishing process. The upper surface of the dielectric layer 300, as well as the channel layer 430, the sacrificial layer 700, and the gate dielectric layer 600 are exposed, and the upper surfaces of the channel layer 430, the sacrificial layer 700, and the gate dielectric layer 600 are flush with the upper surface of the dielectric layer 300. Then, insulation filling materials are filled in the through-hole 420 to form a fill layer 500, and semiconductor materials are filled on the fill layer 500 to form a second semiconductor layer 810. The upper surface of the second semiconductor layer 810 is flush with the upper surface of the dielectric layer 300.

Please refer to FIG. 20, after the second semiconductor layer 810 is formed on the fill layer 500, a third initial blocking layer and a second initial conductive layer are sequentially formed on the upper surfaces of the dielectric layer 300 and the second semiconductor layer 810. A mask layer is formed on the third initial blocking layer and the second initial conductive layer. The mask layer is patterned, and the patterned mask layer is used as a mask. A portion of the second initial conductive layer and the third initial blocking layer are sequentially removed along the vertical direction D2, and the third initial blocking layer and the second initial conductive layer above each second semiconductor layer 810 are retained. The retained third initial blocking layer is formed as a third blocking layer 820, and the retained second initial conductive layer is formed as a second conductive layer 830 (as shown in FIG. 16)

Afterwards, the mask layer above the second conductive layer 830 is removed, and an insulation layer 900 is formed on the side walls of the second conductive layer 830 and the third blocking layer 820. Then, the dielectric materials are deposited on the side wall of the insulation layer 900, and the upper surface of the dielectric layer 300 is flush with the upper surfaces of the second conductive layer 830 and the insulation layer 900. The semiconductor structure 10 formed is shown in FIG. 2. In this way, the second semiconductor layer 810, the second blocking layer 230, and the second conductive layer 830 jointly form a drain layer 800, and the channel layer 430 is electrically connected to the drain layer 800 and the source layer 200 respectively.

It should be noted that the structure in FIG. 3 is based on FIG. 10. When the etching method of Embodiment 3 is used to form a depression 410 on the source layer 200, due to the different etching rates of the source layer 200, and the sacrificial layer 700 as well as the gate dielectric layer 600 which are retained in the through-hole 420, that is, the etching rate of the source layer 200 is greater than that of the sacrificial layer 700 and the gate dielectric layer 600. This results in a faster etching of the source layer 200 and a larger size of the depression 410. Thereby, the fill layer 500 filled in the channel 400 includes a first portion, a second portion and a third portion which are stacked sequentially along the vertical direction D2, and the maximum width W1 of the first portion is greater than the maximum width W2 of the second portion, the maximum width W3 of the third portion is greater than the maximum width W2 of the second portion, and the maximum width W1 of the first portion is greater than the maximum width W3 of the third portion.

The embodiments of the present application provide a semiconductor structure. On the one hand, a source layer and a drain layer are stacked on a substrate, a channel layer is located between the source layer and the drain layer, a gate structure is located on a side wall of the channel layer, a gate dielectric layer is located between the gate structure and the channel layer, and a portion of the dielectric layer is arranged between the source layer and the gate structure. In this way, the space of the semiconductor structure in a vertical direction may be effectively utilized to achieve the purpose of size reduction. On the other hand, the source layer is provided with a depression extending towards a side of the substrate, and the channel layer is partially filled into the depression and electrically connected to the source layer, so as to further reduce the size of the semiconductor structure and meantime improve the conductivity reliability between the channel layer and the source layer, thereby ensuring the performance of the semiconductor structure.

Each embodiment or implementation in the present specification is described in a progressive way, and each embodiment focuses on the differences from other embodiments. The same and similar parts between each embodiment may be referred to each other.

In the description of the present specification, reference terms “one implementation”, “some implementations”, “schematic implementations”, “embodiments”, “specific embodiments”, or “some embodiments” refer to specific features, structures, materials, or characteristics described in combination with implementations or embodiments are included in at least one implementation or embodiment of the present application. In the present specification, the schematic expressions of the above terms do not necessarily refer to the same implementations or embodiment. Moreover, the specific features, structures, materials, or characteristics described may be appropriately combined in any one or more of the implementations or embodiments.

Finally, it should be noted that the above embodiments are only used to illustrate the technical solutions of the present application, but not to limit them; although the present application has been described in detail with reference to the aforementioned embodiments, it should be understood by persons skilled in the art that the technical solutions recorded in the aforementioned embodiments may still be modified or some or all of the technical features thereof may be equivalently replaced; while these modifications or replacements do not depart the essence of the corresponding technical solutions from the scope of the various embodiments of the present application.

What is claimed is:

1. A semiconductor structure, comprising:
a substrate;
a source layer and a drain layer stacked disposed on the substrate;
a channel layer located between the source layer and the drain layer;
a gate structure located on a side wall of the channel layer;
a gate dielectric layer located between the gate structure and the channel layer;
a dielectric layer, a portion of the dielectric layer is arranged between the source layer and the gate structure;
wherein the source layer has a plurality of depressions extending towards the substrate, and the channel layer is partially filled into the depressions and electrically connected to the source layer.

2. The semiconductor structure according to claim 1, further comprising: a fill layer located between the channel layer and the drain layer, and filled into the depression.

3. The semiconductor structure according to claim 1, wherein a contour shape of the depression is arc-shaped or U-shaped.

4. The semiconductor structure according to claim 2, wherein the fill layer comprises a first portion and a second portion, the first portion is located above and in contact with the second portion, and a maximum width W2 of the second portion is smaller than a maximum width W1 of the first portion.

5. The semiconductor structure according to claim 4, wherein the fill layer further comprises a third portion, the second portion is located between the first portion and the third portion, and a maximum width W3 of the third portion is greater than the maximum width W2 of the second portion.

6. The semiconductor structure according to claim 5, wherein the maximum width W3 of the third portion is smaller than the maximum width W1 of the first portion.

7. The semiconductor structure according to claim 1, wherein the gate dielectric layer comprises a first dielectric portion and a second dielectric portion connected to each other, and the second dielectric portion is in direct contact with the channel layer.

8. The semiconductor structure according to claim 7, wherein the second dielectric portion is in direct contact with the source layer.

9. The semiconductor structure according to claim 7, wherein the second dielectric portion is located above the source layer, and a portion of the dielectric layer is located between the second dielectric portion and the source layer.

10. The semiconductor structure according to claim 1, wherein the gate dielectric layer has an L-shaped contour.

11. The semiconductor structure according to claim 1, further comprising: a sacrificial layer located between the gate dielectric layer and the channel layer, and the sacrificial layer has an L-shaped contour.

12. The semiconductor structure according to claim 7, wherein a side wall of the first dielectric portion is in direct contact with the dielectric layer.

13. A preparation method for a semiconductor structure, comprising:
providing a substrate and forming a source layer on the substrate;
forming a dielectric layer on the source layer and forming a gate structure in the dielectric layer;
forming a gate dielectric layer on a side wall of the gate structure;
forming a depression extending towards a side of the substrate on the source layer, and forming a channel layer and making a portion of the channel layer fill into the depression, wherein the channel layer is electrically connected to the source layer; and
forming a drain layer on the channel layer.

14. The preparation method for the semiconductor structure according to claim 13, wherein the method for forming the gate dielectric layer and the gate structure comprises:
forming a plurality of initial gates on the dielectric layer, wherein the plurality of initial gates are arranged on the dielectric layer at intervals along a horizontal direction, and forming an isolation structure between the adjacent initial gates;
forming a first opening extending along a vertical direction in the initial gates, wherein the first opening penetrates a side of the dielectric layer away from the source layer, the source layer being not exposed by the first opening, and forming the retained initial gates as the gate structure; and
forming the gate dielectric layer on the first opening.

15. The preparation method of semiconductor structure according to claim 13, wherein the method for forming the depression on the source layer and forming the channel layer comprises:
removing a portion of the dielectric layer and a portion of the source layer to form a through-hole that runs through the dielectric layer at a center of the gate dielectric layer;
removing a portion of the source layer along an etching direction of the through-hole to form the depression connected to the through-hole on the source layer; and
forming the channel layer on exposed surfaces of the through-hole and the depression.
